(19) United States
(12) Patent Application Publication
(10) Pub. No.: US 2026/0231828 A1
(43) Pub. Date: Aug. 6, 2026

(54) RECONSTITUTED WAFER-TO-WAFER HYBRID BONDING INTERCONNECT ARCHITECTURE WITH KNOWN GOOD DIES

(71) Applicant: Intel Corporation, Santa Clara, CA (US)

(72) Inventors: Omkar KARHADE, Chandler, AZ (US); Nitin A. DESHPANDE, Chandler, AZ (US); Ravindranath V. MAHAJAN, Chandler, AZ (US)

(21) Appl. No.: 19/629,833

(22) Filed: Mar. 26, 2026

Related U.S. Application Data
(63) Continuation of application No. 17/561,720, filed on Dec. 24, 2021.

(51) Int. Cl. H10W 90/00; H10W 20/20; H10W 70/09; H10W 70/60; H10W 72/20; H10W 72/90; H10W 74/01

(52) U.S. Cl. CPC H10W 90/00; H10W 20/20; H10W 70/09; H10W 70/614; H10W 74/014; H10W 74/019; H10W 90/701; H10W 72/241; H10W 72/9413

(57) ABSTRACT

Embodiments disclosed herein include die modules and methods of making die modules. In an embodiment, a die module comprises a first die with a set of first pads with surfaces that are substantially coplanar with a surface of a first dielectric layer. In an embodiment, the die module further comprises a second die with a set of second pads with surfaces that are substantially coplanar with a surface of a second dielectric layer. In an embodiment the first pads are bonded to the second pads and the first dielectric layer is bonded to the second dielectric layer.

### CROSS-REFERENCE TO RELATED APPLICATIONS

This application is a continuation of U.S. patent application Ser. No. 17/561,720, filed on Dec. 24, 2021, the entire contents of which is hereby incorporated by reference herein.

### TECHNICAL FIELD

Embodiments of the present disclosure relate to electronic packages, and more particularly to electronic packages that include die modules that are fabricated with a reconstituted wafer-to-wafer hybrid bonding interconnect (HBI) architecture.

### BACKGROUND

Multi-die modules are of growing importance in the semiconductor industry. In some implementations, a base die is provided and a plurality of chiplets are mounted to the base die. The base die electrically couples together the chiplets. In some instances, the chiplets are bonded to the base die with first level interconnects (FLIs). In some instances, the base die can be bonded to the chiplets with a hybrid bonding interconnect (HBI) architecture. In an HBI architecture, each side of the interconnect includes copper bumps that are embedded in a dielectric layer, such as an oxide. The opposing copper bumps are bonded to each other, and the dielectric layers are bonded to each other. Collective bonding of singulated dies on wafer with hybrid bonding enables fast hybrid bonding, but such bonding is sensitive to defects from die singulation, thinning, as well as die thickness variation.

### BRIEF DESCRIPTION OF THE DRAWINGS

FIG. 1 is a cross-sectional illustration of an electronic package with a die module that includes chiplets that are hybrid bonded to a base die, in accordance with an embodiment.

FIGS. 2A-2I are cross-sectional illustrations of a process for assembling a die module with chiplets hybrid bonded to a base die, in accordance with an embodiment.

FIG. 3A is a cross-sectional illustration of a die module with chiplets that include through silicon vias (TSVs) for thermal management, in accordance with an embodiment.

FIG. 3B is a cross-sectional illustration of a die module with fluidic channels over the chiplets in order to enhance thermal management, in accordance with an embodiment.

FIG. 3C is a cross-sectional illustration of a die module with chiplets that are hybrid bonded to a carrier, in accordance with an embodiment.

FIG. 3D is a cross-sectional illustration of a die module with chiplets that are thermally coupled to a metal substrate, in accordance with an embodiment.

FIG. 4 is a cross-sectional illustration of an electronic system with a die module that includes chiplets that are hybrid bonded to a base die, in accordance with an embodiment.

FIG. 5 is a cross-sectional illustration of an electronic package with a pair of base dies in a mold layer and a plurality of chiplets coupled to the base dies, in accordance with an embodiment.

FIGS. 6A-6H are cross-sectional illustrations of a process for assembling a die module with a pair of base dies in a mold layer and a plurality of chiplets coupled to the base dies, in accordance with an embodiment.

FIG. 7A is a cross-sectional illustration of a die module with chiplets that include through silicon vias, in accordance with an embodiment.

FIG. 7B is a cross-sectional illustration of a die module with chiplets that are below fluidic channels for thermal management, in accordance with an embodiment.

FIG. 7C is a cross-sectional illustration of a die module with chiplets that are hybrid bonded to a carrier, in accordance with an embodiment.

FIG. 7D is a cross-sectional illustration of a die module with chiplets that are thermally coupled to a metal substrate, in accordance with an embodiment.

FIG. 8 is a cross-sectional illustration of an electronic system with a die module that comprises a pair of base dies in a mold layer with chiplets coupled to the base dies, in accordance with an embodiment.

FIG. 9 is a schematic of a computing device built in accordance with an embodiment.

### EMBODIMENTS OF THE PRESENT DISCLOSURE

Described herein are electronic packages that include die modules that are fabricated with a reconstituted wafer-to-wafer hybrid bonding interconnect (HBI) architecture, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, hybrid bonding interconnect (HBI) interfaces are susceptible to foreign material contamination that negatively impacts the connections between the die and the chiplets. Accordingly, embodiments disclosed herein include HBI interfaces that are formed immediately after polishing processes (e.g., chemical mechanical polishing (CMP)). Embodiments disclosed herein also allow for known good die (KGD) architectures, as the chiplets and base dies can be tested before integration into the die module. The assembly architectures described herein also allow for no need for tight thickness control. As such, embodiments disclosed herein include higher hybrid bonding yields than existing topologies.

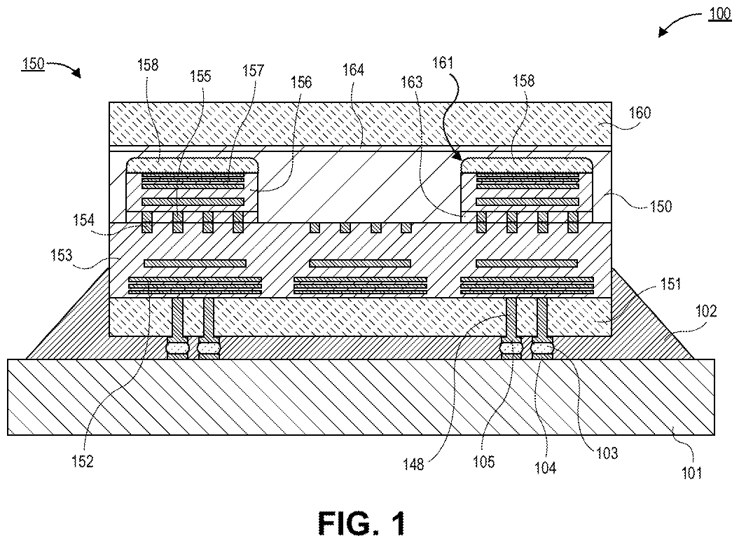

Referring now to FIG. 1, a cross-sectional illustration of an electronic package 100 is shown, in accordance with an embodiment. In an embodiment, the electronic package 100 comprise a package substrate 101. The package substrate 101 may be a cored or coreless substrate that includes conductive routing (not shown). For example, conductive routing may couple the overlying die module 150 to an underlying board (not shown). The package substrate 101 may also comprises embedded passive structures (e.g., capacitors, inductors, transformers, etc.) or active devices (e.g., transistor devices).

In an embodiment, the package substrate 101 may be coupled to a die module 150 by interconnects 103. For example, interconnects 103 may be solder balls that couple pads 105 on the die module 150 to pads 104 on the package substrate 101. While shown as solder balls, it is to be appreciated that the interconnects 103 may be any suitable interconnect architecture. In an embodiment, an underfill 102 may surround the interconnects 103 between the die module 150 and the package substrate 101.

In an embodiment, the die module 150 may comprise a base die 151. The base die 151 may include a silicon substrate, or other semiconductor material. The base die 151 may comprise transistor devices. That is, the base die 151 may be an active device. In other embodiments, the base die 151 may comprise high density routing. For example, the base die 151 may be a passive base die 151. In an embodiment, backend layers 153 may be provided over the base die 151. For example, the backend layers 153 may comprise conductive routing 152 that couples the circuitry on the base die 151 with pads 154. In the illustrated embodiment, the conductive routing 152 is shown as a plurality of conductive planes for simplicity. However, it is to be appreciated that the conductive routing 152 may comprise conductive planes, conductive traces, conductive vias, conductive pads, and the like. Base die 151 may also comprise TSVs 148.

In an embodiment, the backend layers 153 may comprise a dielectric material. For example, the backend layers 153 may include an oxide material (e.g., silicon oxide (SiO₂)). In an embodiment, pads 154 may be provided in the backend layers 153. The pads 154 may comprise copper pads. The pads 154 may be embedded in the backend layers 153 so that surfaces of the pads 154 are substantially coplanar with a surface of the backend layers 153.

In an embodiment, a plurality of dies 158 may be coupled to the base die 151. The plurality of dies 158 may have widths that are less than a width of the base die 151. In an embodiment, the plurality of dies 158 may sometimes be referred to as chiplets. The plurality of dies 158 may be processors, graphics processors, memory dies, systems on a chip (SoCs), or the like. In an embodiment, a thickness of the dies 158 may be thinner than a thickness of the base die 151. In a particular embodiment, the dies 158 may have rounded corners 161 characteristic of a polishing process used to thin the dies 158 during assembly processes.

The dies 158 may include backend layers 156. The backend layers 156 may include conductive routing 157. Traces are shown in FIG. 1, but it is to be appreciated that embodiments may include conductive routing 157 with traces, vias, planes, and the like. In an embodiment, the backend layers 156 may comprise a dielectric material, such as an oxide or the like. In an embodiment, pads 155 may be coupled to the dies 158 by the conductive routing 157. In an embodiment, the pads 155 may be embedded in a dielectric layer 163. For example, a surface of the pads 155 may be substantially coplanar with a surface of the dielectric layer 163.

In an embodiment, the dies 158 may be embedded in a fill layer 159. The fill layer 159 may be an organic or inorganic material. In some embodiments, the fill layer 159 may comprise two or more different materials or material layers. In an embodiment, the fill layer 159 may comprise silicon and oxygen (e.g., SiO₂). The fill layer 159 may surround sidewall surfaces of the dies 158 and backside surfaces of the dies 158.

In an embodiment, the backside of the fill layer 159 may be bonded to a dielectric layer 164 of a carrier 160. That is, a dielectric-to-dielectric bond may be provided between the carrier 160 and the backside of the dies 158. In an embodiment, the carrier 160 may be a semiconductor substrate. For example, the carrier 160 may be a silicon carrier.

As shown, the dies 158 may be coupled to the base die 151 by a hybrid bonding interconnect (HBI) architecture. Particularly, pads 155 of the first dies may be bonded to pads 154 of the base die 151. In some instances, the bonding between the pads 155 and 154 may be such that there is no visible seam between the two pads 155 and 154. Additionally, the dielectric layers 163 and 153 may also bond together. That is, there is a bonding interface that includes two types of bonds (e.g., copper-to-copper and oxide-to-oxide). Additionally, it is to be appreciated that such bonding architectures enable small pitch connections which enables more interconnects per unit area. For example, a pitch of the pads 155 and 154 may be approximately 20 μm or less, approximately 10 μm or less, or less than approximately 1 μm (e.g., as small as a few hundred nanometers). As used herein, approximately may refer to a value that is within 10% of the stated value. For example, approximately 10 μm may refer to a range between 9 μm and 11 μm.

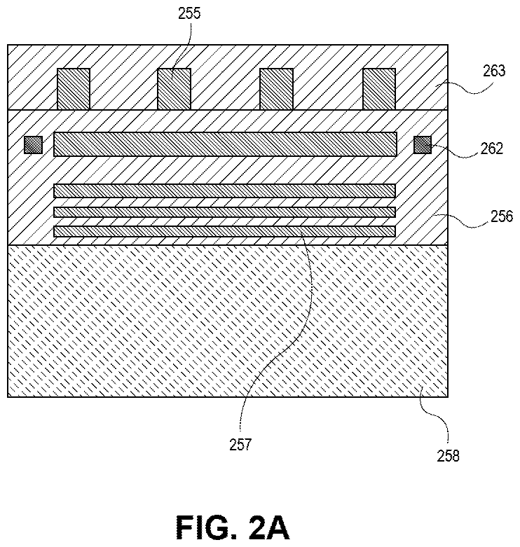

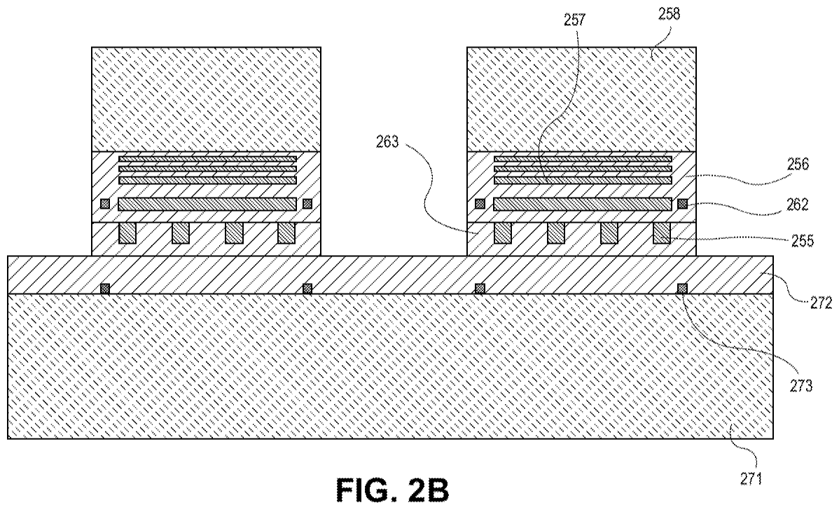

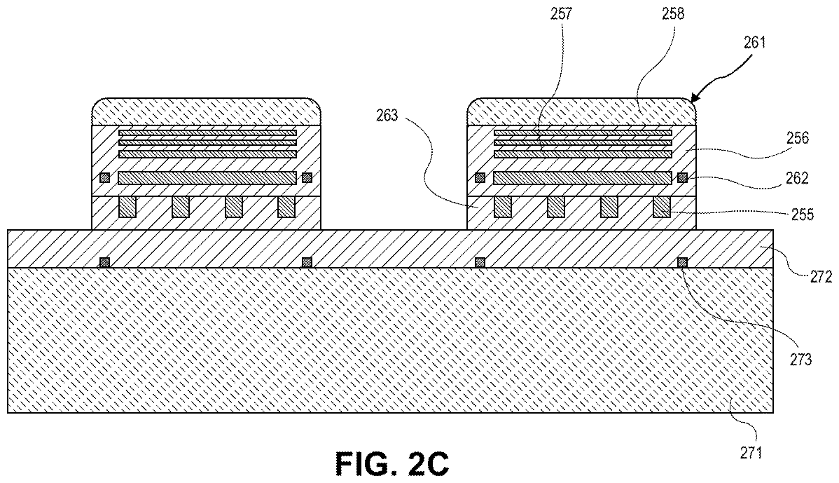

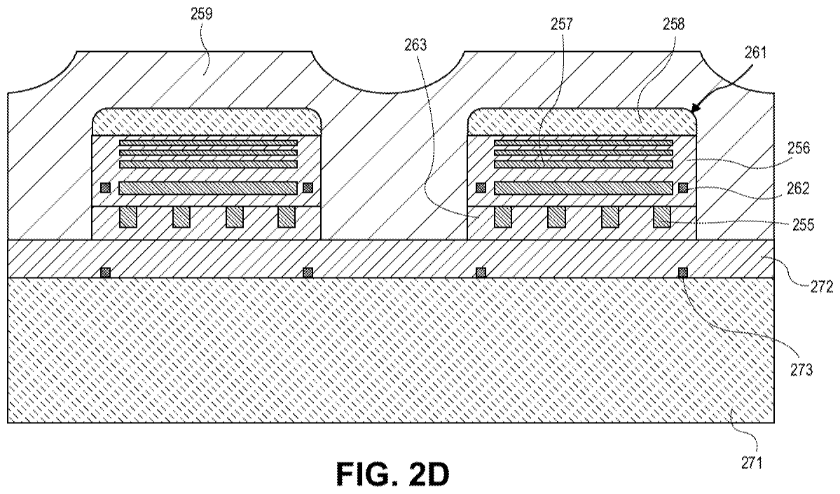

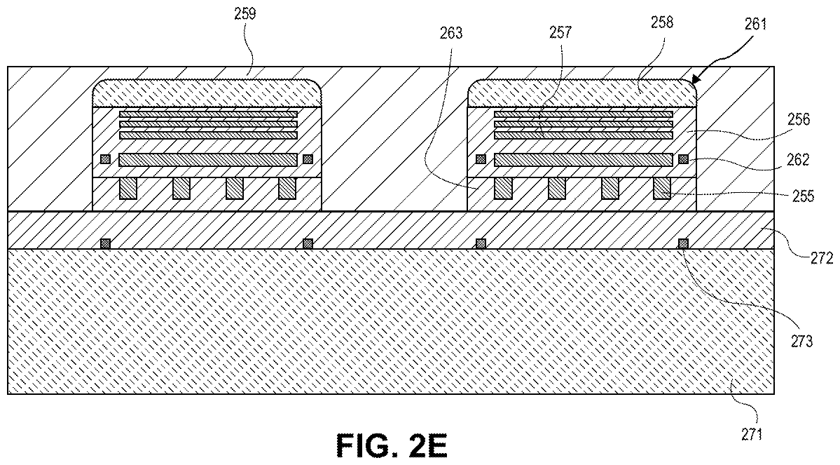

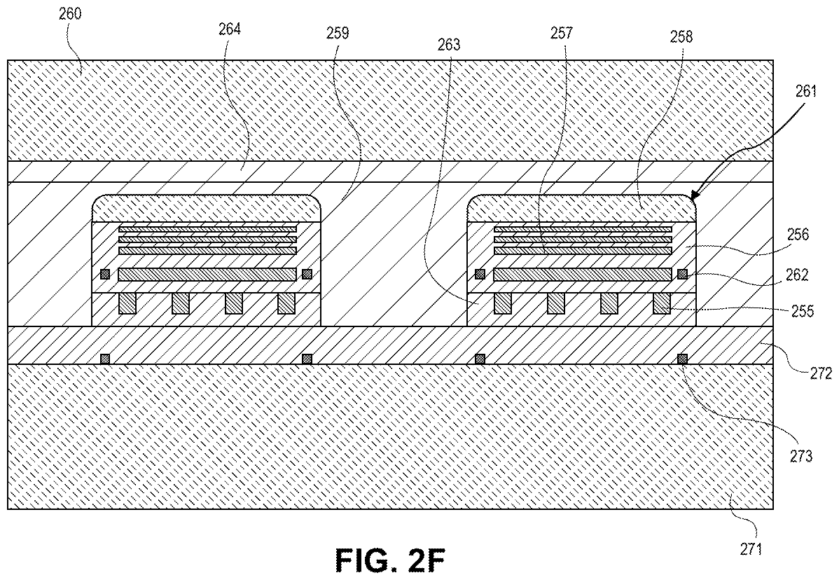

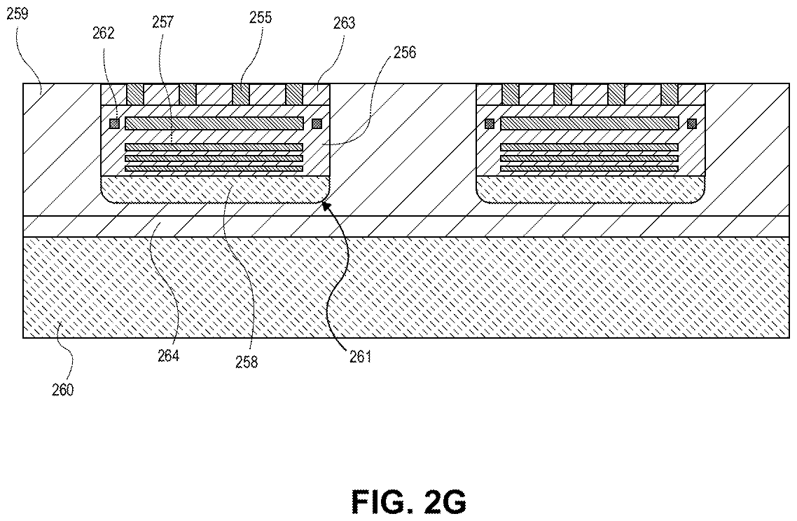

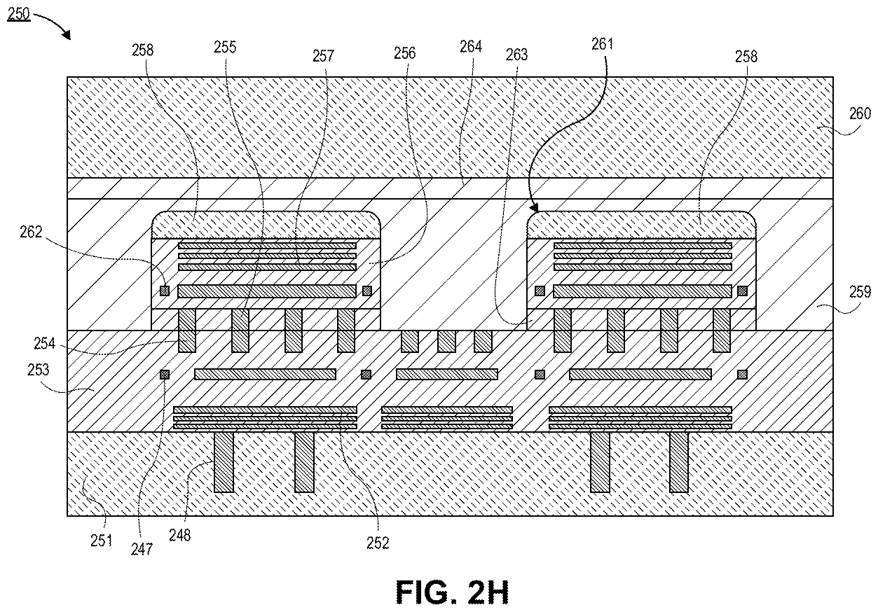

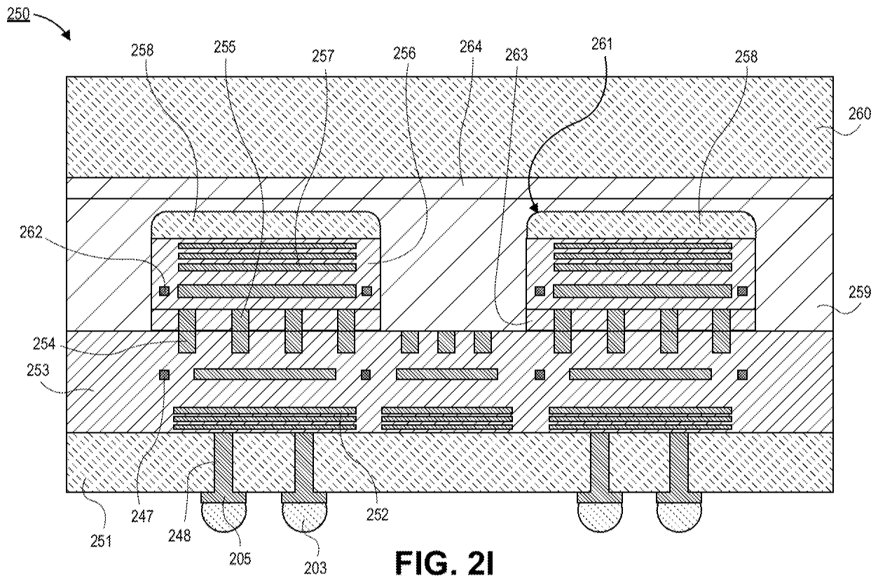

Referring now to FIGS. 2A-2I, a series of cross-sectional illustrations depicting a process for assembling a die module, such as the die module 150 shown in FIG. 1 is shown, in accordance with an embodiment.

Referring now to FIG. 2A. a cross-sectional illustration of a die 258 is shown, in accordance with an embodiment. In an embodiment, the die 258 may be a chiplet or the like that will be mounted to a larger base die in a subsequent processing operation. For example, the die 258 may be a processor, a graphics processor, a memory die, an SoC, or any other type of die 258. In an embodiment, the die 258 may comprise a silicon die or any other suitable semiconductor material. A plurality of conductive routing 257 may be provided over the semiconductor material of the die 258. For example, the conductive routing 257 may include traces, vias, pads, and the like in order to electrically couple transistors and other structures on the die 258 with pads 255. In an embodiment, the conductive routing 257 may be formed in dielectric backend layers 256. For example, the backend layers 256 may comprise an oxide, such as an oxide of silicon (e.g., SiO₂).

In an embodiment, one or more fiducial marks 262 may be provided in the backend layers 256. The fiducial marks 262 may be marks used to improve alignment between the die 258 and a subsequently attached substrate or die. In an embodiment, any fiducial mark architecture may be used. For example, the fiducial marks may be a box, a cross, or the like. In the illustrated embodiment, a pair of fiducial marks 262 are shown. However, it is to be appreciated that any number of fiducial marks may be used, in accordance with an embodiment. For example, fiducial marks 262 may be provided at each corner of the die 258.

In an embodiment a plurality of pads 255 are provided over the backend layers 256. The pads 255 may be copper pads suitable for HBI topologies. For example, a pitch of the pads 255 may be approximately 20 μm or less, approximately 10 μm or less, or less than approximately 1 μm (e.g., as small as a few hundred nanometers). In an embodiment, the pads 255 may be coupled to the die 258 by the conductive routing 257. The pads 255 may also be surrounded by an additional dielectric layer 263. For example, the dielectric layer 263 may comprise silicon and oxygen (e.g., SiO₂). A thickness of the dielectric layer 263 may be greater than a thickness of the pads 255. As such, the pads 255 are entirely embedded within the dielectric layer 263.

Referring now to FIG. 2B, a cross-sectional illustration of the device after a pair of dies 258 are mounted to a first carrier 271 is shown, in accordance with an embodiment. In an embodiment, the dies 258 may be flipped over compared to the orientation shown in FIG. 2A. The dielectric layer 263 may be set down onto a dielectric layer 272 over the first carrier 271. In an embodiment, the dielectric layer 263 and the dielectric layer 272 bond with a dielectric-to-dielectric bonding process. In some embodiments, van-der walls forces are sufficient to attach the two dielectric layers 263 and 272. In other embodiments, a low temperature annealing process (e.g., 160° C. to 180° C.) is used to fuse the dielectric layers 263 and 272 to make a permanent bond. In some other embodiments, the bond between the dies 258 and the first carrier 271 may be implemented by an adhesive bonding process. In an embodiment, the first carrier 271 may be any suitable ridged material. For example, the first carrier 271 may be a silicon substrate or the like. In other embodiments the first carrier 271 may be a glass substrate.

In an embodiment, fiducial marks 273 may be provided on the first carrier 271. The fiducial marks 273 can be aligned with the fiducial marks 262 on the dies 258 in order to provide the proper orientation and positioning of the dies 258 on the first carrier 271. In an embodiment, the fiducial marks 273 may be provided on a top surface of the first carrier 271, and the dielectric layer 272 surrounds the fiducial marks 273.

It is to be appreciated that the dies 258 may be known good dies (KGD). That is, the dies 258 may be tested prior to being attached to the first carrier 271. In some embodiments, the dies 258 are tested before being singulated, or the dies 258 are tested after being singulated but before the attachment to the first carrier 271. Additionally, it is to be appreciated that foreign material may be provided between the dies 258 and the first carrier 271. That is, the surfaces of the dies 258 and the carrier 271 do not need to be pristine at this point in the assembly. This is because the interface between the dielectric layer 263 and the dielectric layer 272 will be polished away in a subsequent polishing operation.

Referring now to FIG. 2C, a cross-sectional illustration of the structure after a substrate thinning process is shown, in accordance with an embodiment. In an embodiment, a grinding process may be implemented in order to reduce a thickness of the dies 258. For example, the thickness of the dies 258 may be reduced to approximately 20 μm or less, or approximately 10 μm or less. The grinding process may also result in the corners 261 of the dies 258 being rounded. The rounded corners 261 are on the surface of the dies 258 opposite from the pads 255.

Referring now to FIG. 2D, a cross-sectional illustration of the structure after a fill layer 259 is disposed around the dies 258 is shown, in accordance with an embodiment. In an embodiment, the fill layer 259 may be an oxide or other filler material. In general, filler material is high temperature process compatible, has a low deposition temperature, and a low coefficient of thermal expansion (CTE). The fill layer 259 may fill the gaps between the dies 258. Portions of the fill layer 259 may be in direct contact with the dielectric layer 272. Additionally, while shown as a single fill layer 259, it is to be appreciated that multiple different fill layers may be used. For example, the fill layer 259 may comprise a first layer with improved mechanical properties, and a second layer over the first layer that has a faster deposition process.

Referring now to FIG. 2E, a cross-sectional illustration of the structure after the fill layer 259 is recessed is shown, in accordance with an embodiment. In an embodiment, the fill layer 259 may be recessed with a grinding or polishing process, such as a chemical mechanical polishing (CMP) process. In an embodiment, the fill layer 259 may be recessed so that a thin layer of the fill layer 259 remains over a back surface of the dies 258.

Referring now to FIG. 2F, a cross-sectional illustration of the structure after a second carrier 260 is attached to the first carrier 271 is shown, in accordance with an embodiment. In an embodiment, the second carrier 260 may be bonded to the fill layer 259 with a dielectric-to-dielectric bonding. For example, the second carrier 260 may include a dielectric layer 264, such as a silicon oxide (e.g., SiO₂) that is bonded to the fill layer 259. In an embodiment, the bonding strength is sufficient without an annealing process. In other embodiments, an annealing process is used to improve the bond. For example, an annealing process of between 160° C. and 180° C. may be used in some embodiments. Alternatively, an adhesive based bonding process between the second carrier 260 and the fill layer 259 may be used in some embodiments instead of dielectric-to-dielectric bond. In an embodiment, the second carrier 260 may be a semiconductor substrate, such as a silicon substrate. In other embodiments, the second carrier 260 may be another rigid material, such as glass or the like.

Referring now to FIG. 2G, a cross-sectional illustration of the structure after the first carrier 271 is removed is shown, in accordance with an embodiment. In an embodiment, the first carrier 271 and the dielectric layer 272 may be removed with a grinding or polishing process, such as a CMP process. The polishing process results in the exposure of pads 255 and the dielectric layer 263. At this point, the pads 255 are substantially clear of foreign material, and have a pristine surface.

Referring now to FIG. 2H, a cross-sectional illustration of the structure after the dies 258 are bonded to a base die 251 is shown, in accordance with an embodiment. In an embodiment, the bonding may be an HBI architecture. For example, the pads 255 may be provided over pads 254 on the base die 251. Additionally, the dielectric layer 263 may interface with a dielectric backend layer 253 of the base die 251. In an embodiment, a low temperature process results in the dielectric layer 263 and the backend layer 253 bonding together. At a higher temperature anneal, the pads 255 may bond with the pads 254 with a solid state diffusion bonding process. In some embodiments, there may not be a discernable seam at the interface between the pads 254 and the pads 255.

In an embodiment, the base die 251 may be a passive die or an active die. In some embodiments where the base die 251 is a passive die, the base die 251 merely couples together the dies 258 with high density routing. In other embodiments, the base die 251 includes functional circuitry. For example, the die 251 may include logic and/or memory blocks that are used in the processing of data in the die module 250.

In an embodiment, the base die 251 may comprise fiducial marks 247 that are used to align the dies 258 to the base die 251. In an embodiment, the base die 251 may further comprise conductive routing 252 provided in the dielectric backend layer 253. The conductive routing 252 may include vias, traces, pads, and the like in order to couple the pads 254 to circuitry or other routing on the die surface of the base die 251. In an embodiment, the base die 251 may also include through substrate vias 248, commonly referred to as through silicon vias (TSVs). The TSVs 248 may be formed partially through a thickness of the base die 251.

Referring now to FIG. 2I, a cross-sectional illustration of the die module 250 after the TSVs 248 are revealed is shown, in accordance with an embodiment. In an embodiment, the TSVs 248 may be revealed by a polishing or grinding process of the backside of the base die 251. The recessing removes portions of the base die 251 until the TSVs 248 are exposed. After the TSVs 248 are exposed pads 205 may be formed over a backside of the base die 251. In the illustrated embodiment, the pads 205 are shown as being directly on the base die 251. However, in some embodiments, one or more redistribution layers may be provided between the TSVs 248 and the pads 205. In an embodiment, bumps 203, such as solder bumps, may be plated on the pads 205 in order to prepare for attachment to a package substrate (not shown).

It is to be appreciated that only a single instance of the die module 250 is shown in the FIGS. 2A-2I. However, it is to be appreciated that a plurality of die modules 250 may be fabricated substantially in parallel using wafer level processes or other larger form factors. In such embodiments, the individual die modules 250 may be singulated after the operations shown in FIG. 2I in order to provide individual die modules 250.

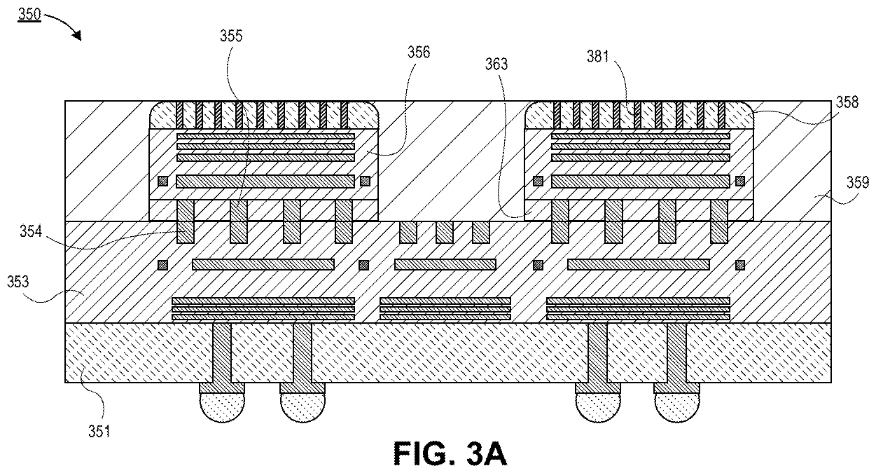

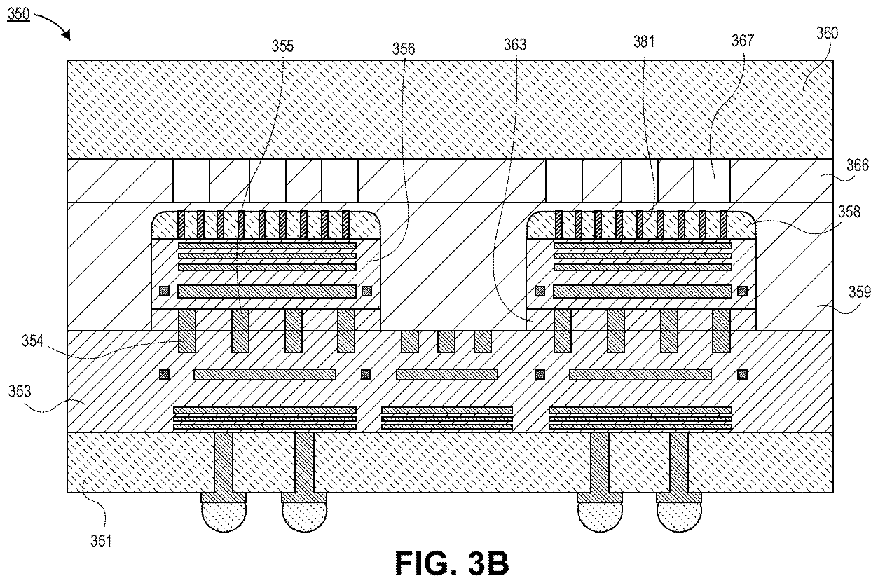

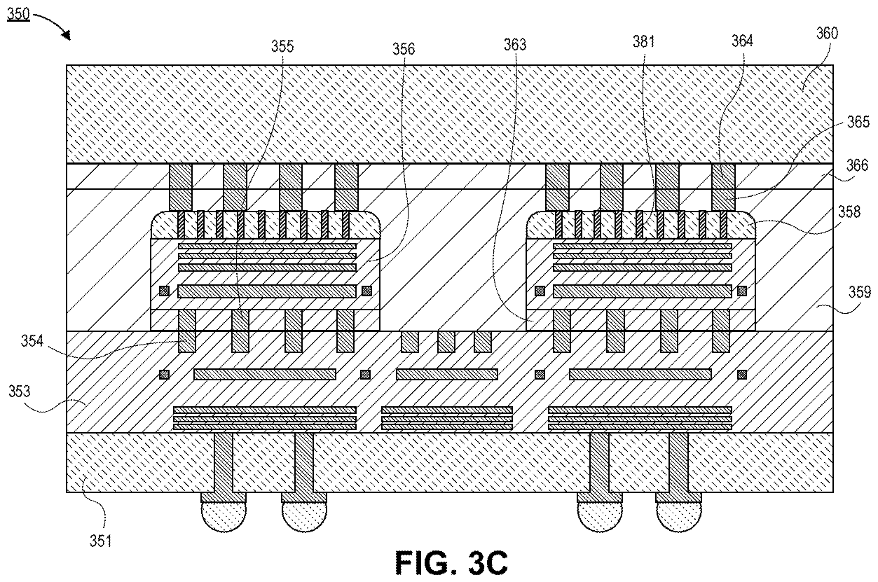

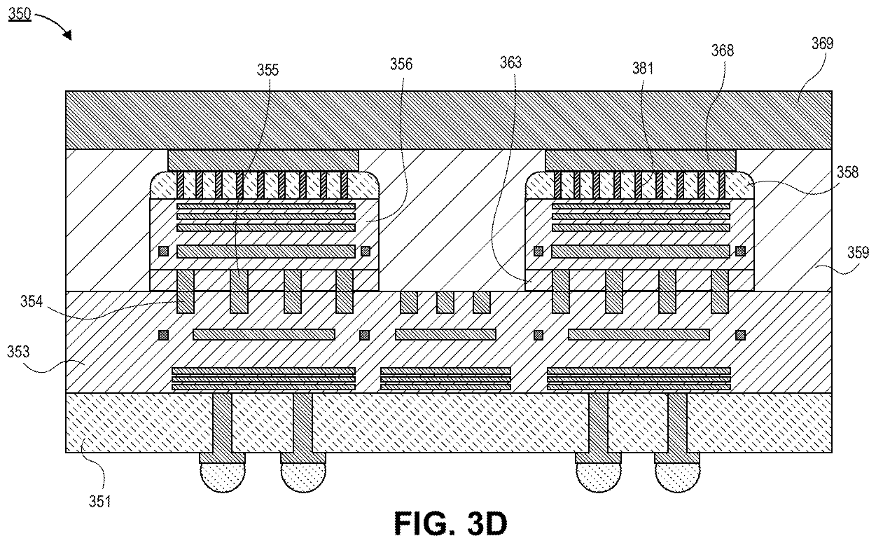

Referring now to FIGS. 3A-3D, a series of cross-sectional illustrations depicting a plurality of different die modules 350 is shown, in accordance with an embodiment. The illustrated embodiments may include improved thermal performance compared to the embodiment shown in FIG. 2I.

Referring now to FIG. 3A, a cross-sectional illustration of a die module 350 is shown, in accordance with an embodiment. In an embodiment, the die module 350 includes a base die 351. The base die 351 may have a backend dielectric layer 353. Pads 354 may be provided at a top surface of the backend dielectric layer 353. A plurality of second dies 358 may be coupled to the base die 351. For example, pads 355 may be provided in a dielectric layer 363 of the second dies 358. In an embodiment, the pads 355 and the dielectric layer 363 may be bonded to the pads 354 and the backend dielectric layer 353 with an HBI architecture. That is, the pads 355 and 354 may undergo solid state diffusion in an annealing process in some embodiments.

In an embodiment, the second dies 358 may be surrounded by a filler layer 359. The filler layer 359 may be an oxide or the like. In some embodiments, the filler layer 359 may comprise two or more layers, as described in greater detail above. The second dies 358 may also comprise a backend dielectric layer 356 that couples the pads 355 to a die surface.

In the particular embodiment shown in FIG. 3A, the carrier substrate over a backside surface of the second dies 358 is omitted. Instead of the carrier, the die module 350 is polished back to expose the backside surfaces of the second dies 358. Additionally, TSVs 381 may be formed through the second dies 358. The TSVs 381 may be used for thermal regulation. That is, in some embodiments, the TSVs 381 are not electrically coupled to active circuitry of the second dies 358.

Referring now to FIG. 3B, a cross-sectional illustration of a die module 350 is shown, in accordance with an additional embodiment. In an embodiment, the die module 350 comprises a base die 351 and a pair of second dies 358 that are bonded to the base die 351 with an HBI architecture. For example, pads 354 in the backend dielectric layer 353 are bonded to pads 355 in dielectric layer 363. In contrast to the embodiment shown in FIG. 3A, the carrier 360 remains in the structure. However, the dielectric layer 366 between the carrier 360 and the fill layer 359 is increased in thickness, compared to the embodiment shown in FIG. 2I above. However, thermal control is still improved because fluidic channels 367 are provided through the dielectric layer 366. In an embodiment, a liquid cooling solution or a gas may be flown through the fluidic channels 367 in order to remove thermal energy from the backside of the second dies 358. While shown as being only over the dies 358, it is to be appreciated that the fluidic channels 367 may also be between the dies 358. Similarly, the other thermal solutions described in FIGS. 3A-3D may also include thermal solutions between the dies 358. The second dies 358 may further comprise thermal TSVs 381 that pass thermal energy through the second dies 358.

Referring now to FIG. 3C, a cross-sectional illustration of a die module 350 is shown, in accordance with another embodiment. In an embodiment, the die module 350 may include a base die 351 and a plurality of second dies 358 coupled to the base die 351 by an HBI architecture. For example, pads 354 in the backend dielectric layer 353 are bonded to pads 355 in dielectric layer 363. In an embodiment, the backside of the second dies 358 may be thermally coupled to the carrier 360 through a second HBI interface. As shown, pads 365 may be provided over a backside surface of the second dies 358. Additionally, pads 364 may pass through the dielectric 366 on the carrier 360. The pads 365 and 364 may be bonded with an annealing process. The bonding may also result in the dielectric 366 bonding with the dielectric of the fill layer 359. In an embodiment, the pads 365 and 364 may be only for thermal control. That is, the pads 365 and 364 may not be electrically coupled to functional circuitry of the die module 350. The second dies 358 may further comprise thermal TSVs 381 that pass thermal energy through the second dies 358.

Referring now to FIG. 3D, a cross-sectional illustration of a die module 350 is shown, in accordance with an additional embodiment. In an embodiment, the die module 350 may include a base die 351 and a plurality of second dies 358 coupled to the base die 351 by an HBI architecture. For example, pads 354 in the backend dielectric layer 353 are bonded to pads 355 in dielectric layer 363. In an embodiment, the backside of the second dies 358 may be thermally coupled to the carrier 369 through metal slugs 368. In an embodiment, the carrier 369 may comprise a high thermal conductivity material. For example, the carrier 369 may comprise copper or the like. As such, a high amount of thermal energy may be pulled from the backside of the second dies 358. The second dies 358 may further comprise thermal TSVs 381 that pass thermal energy through the second dies 358.

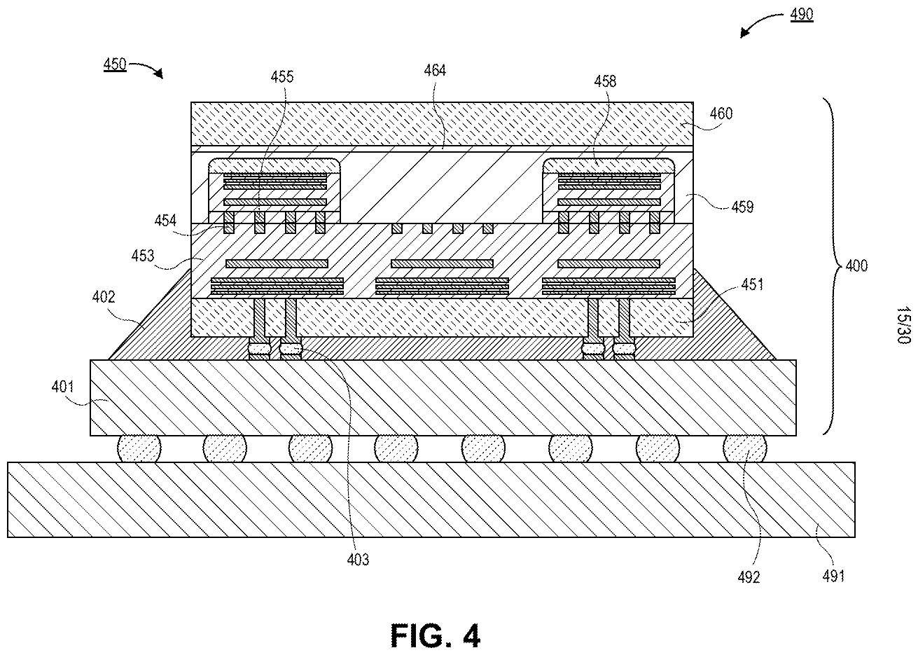

Referring now to FIG. 4, a cross-sectional illustration of an electronic system 490 is shown, in accordance with an embodiment. In an embodiment, the electronic system 490 may comprise a board 491, such as a printed circuit board (PCB). In an embodiment, the board 491 is coupled to an electronic package 400 by interconnects 492. The interconnects 492 are shown as solder balls, but it is to be appreciated that sockets or the like may also couple the package substrate 401 to the board 491. In an embodiment, the electronic package 400 may comprise a package substrate 401 and a die module 450. The die module 450 may be coupled to the package substrate by interconnects 403. The interconnects 403 may be surrounded by an underfill 402.

In an embodiment, the die module 450 may be substantially similar to any of the die modules described in greater detail above. For example, the die module 450 may comprise a base die 451. A backend dielectric layer 453 may comprise pads 454 that are bonded to pads 455 of a second die 458. The bonding interface between the second dies 458 and the base die 451 may be an HBI architecture. In an embodiment, the second dies 458 may be surrounded by a fill layer 459. The fill layer 459 may be bonded to a dielectric layer 464 that is attached to a carrier 460.

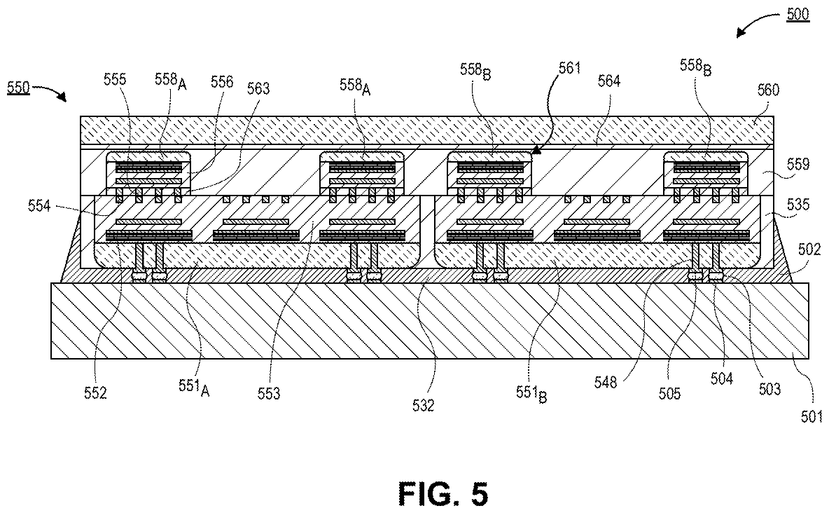

Referring now to FIG. 5 a cross-sectional illustration of an electronic package 500 is shown, in accordance with an embodiment. In an embodiment, the electronic package 500 comprise a package substrate 501. The package substrate 501 may be a cored or coreless substrate that includes conductive routing (not shown). For example, conductive routing may couple the overlying die module 550 to an underlying board (not shown). The package substrate 501 may also comprises embedded passive structures (e.g., capacitors, inductors, transformers, etc.) or active devices (e.g., transistor devices).

In an embodiment, the package substrate 501 may be coupled to a die module 550 by interconnects 503. For example, interconnects 503 may be solder balls that couple pads 505 on the die module 550 to pads 504 on the package substrate 501. While shown as solder balls, it is to be appreciated that the interconnects 503 may be any suitable interconnect architecture. In an embodiment, an underfill 502 may surround the interconnects 503 between the die module 550 and the package substrate 501. Pads 505 may be coupled to TSVs 548 through the base dies 551_{A} and 551_{B}.

In an embodiment, the die module 550 may comprise two or more base dies 551_{A} and 551_{B}. For example, a first base die 551_{A} and a second base die 551_{B} are provided in the die module 550. The base dies 551_{A} and 551_{B} may include a silicon substrate, or other semiconductor material. The base dies 551_{A} and 551_{B} may comprise transistor devices. That is, the base dies 551_{A} and 551_{B} may be active devices. In other embodiments, the base dies 551_{A} and 551_{B} may comprise high density routing. For example, the base dies 551_{A} and 551_{B} may be passive base dies 551_{A} and 551_{B}. In an embodiment, backend layers 553 may be provided over the base dies 551_{A} and 551_{B}. For example, the backend layers 553 may comprise conductive routing 552 that couples the circuitry on the base dies 551_{A} and 551_{B} with pads 554. In the illustrated embodiment, the conductive routing 552 is shown as a plurality of conductive planes for simplicity. However, it is to be appreciated that the conductive routing 552 may comprise conductive planes, conductive traces, conductive vias, conductive pads, and the like.

In an embodiment, the backend layers 553 may comprise a dielectric material. For example, the backend layers 553 may include an oxide material (e.g., silicon oxide (SiO₂)). In an embodiment, pads 554 may be provided in the backend layers 553. The pads 554 may comprise copper pads. The pads 554 may be embedded in the backend layers 553 so that surfaces of the pads 554 are substantially coplanar with surfaces of the backend layers 553. In an embodiment, the base dies 551_{A} and 551_{B} and the backend layers 553 may be surrounded by a fill layer 535. The fill layer 535 may also be a dielectric material such as silicon oxide.

In an embodiment, a plurality of second dies 558 558_{A} and 558_{B} may be coupled to the base dies 551_{A} and 551_{B}. For example second dies 558_{A} are coupled to the base die 551_{A}, and second dies 558_{B} are coupled to the base die 551_{B}. The plurality of dies 558 may have widths that are less than widths of the base dies 551_{A} and 551_{B}. In an embodiment, the plurality of dies 558_{A} and 558_{B} may sometimes be referred to as chiplets. The plurality of dies 558_{A} and 558_{B} may be processors, graphics processors, memory dies, systems on a chip (SoCs), or the like. In an embodiment, a thickness of the dies 558_{A} and 558_{B} may be thinner than a thickness of the dies 551_{A} and 551_{B}. In a particular embodiment, the dies 558_{A} and 558_{B} may have rounded corners 561 characteristic of a polishing process used to thin the dies 558_{A} and 558_{B} during assembly processes. Similarly, base dies 551_{A} and 551_{B} may also have rounded corners 532 due to grinding processes.

The dies 558_{A} and 558_{B} may include backend layers 556. The backend layers 556 may include conductive routing 557. Traces are shown in FIG. 5, but it is to be appreciated that embodiments may include conductive routing 557 with traces, vias, planes, and the like. In an embodiment, the backend layers 556 may comprise a dielectric material, such as an oxide or the like. In an embodiment, pads 555 may be coupled to the dies 558_{A} and 558_{B} by the conductive routing 557. In an embodiment, the pads 555 may be embedded in a dielectric layer 563. For example, a surface of the pads 555 may be substantially coplanar with a surface of the dielectric layers 563.

In an embodiment, the dies 558_{A} and 558_{B} may be embedded in a fill layer 559. The fill layer 559 may be an organic or inorganic material. In some embodiments, the fill layer 559 may comprise two or more different materials or material layers. In an embodiment, the fill layer 559 may comprise silicon and oxygen (e.g., SiO₂). The fill layer 559 may surround sidewall surfaces of the dies 558_{A} and 558_{B} and a backside surfaces of the dies 558_{A} and 558_{B}.

In an embodiment, the backside of the fill layer 559 may be bonded to a dielectric layer 564 of a carrier 560. That is, a dielectric-to-dielectric bond may be provided between the carrier 560 and the backside of the dies 558_{A} and 558_{B}. In an embodiment, the carrier 560 may be a semiconductor substrate. For example, the carrier 560 may be a silicon carrier.

As shown, the dies 558_{A} and 558_{B} may be coupled to the base dies 551_{A} and 551_{B} by an HBI architecture. Particularly, pads 555 of the first dies may be bonded to pads 554 of the base dies 551_{A} and 551_{B}. In some instances, the bonding between the pads 555 and 554 may be such that there is no visible seam between the two pads 555 and 554. Additionally, the dielectric layers 563 and 553 may also bond together. That is, there is a bonding interface that includes two types of bonds (e.g., copper-to-copper and oxide-to-oxide). Additionally, it is to be appreciated that such bonding architectures enable small pitch connections which enables more interconnects per unit area. For example, a pitch of the pads 555 and 554 may be approximately 20 μm or less, approximately 10 μm or less, or less than approximately 1 μm (e.g., as small as a few hundred nanometers).

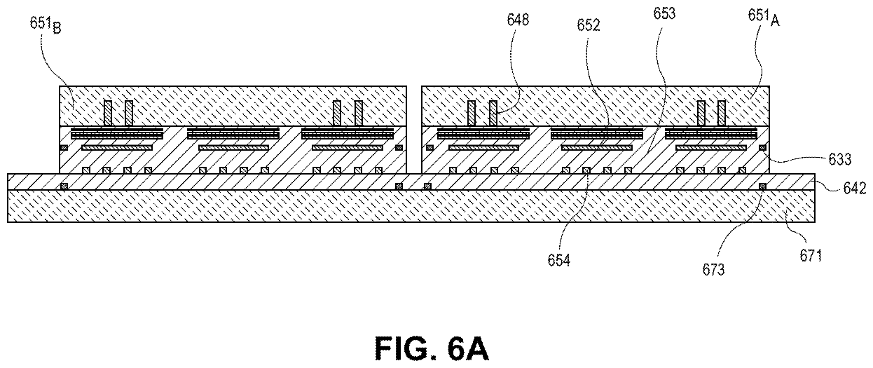

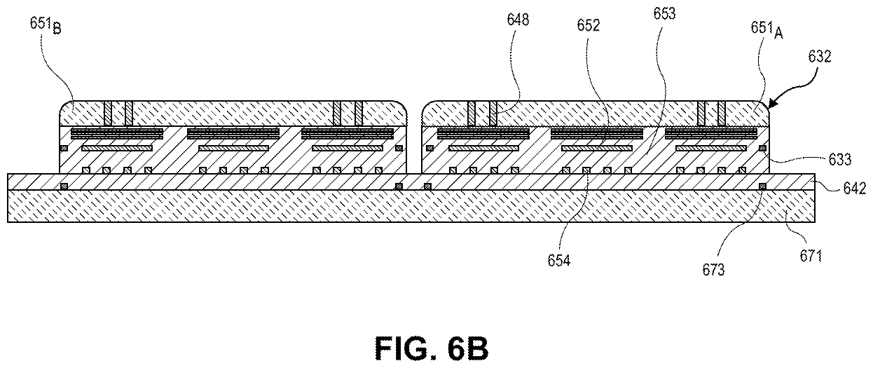

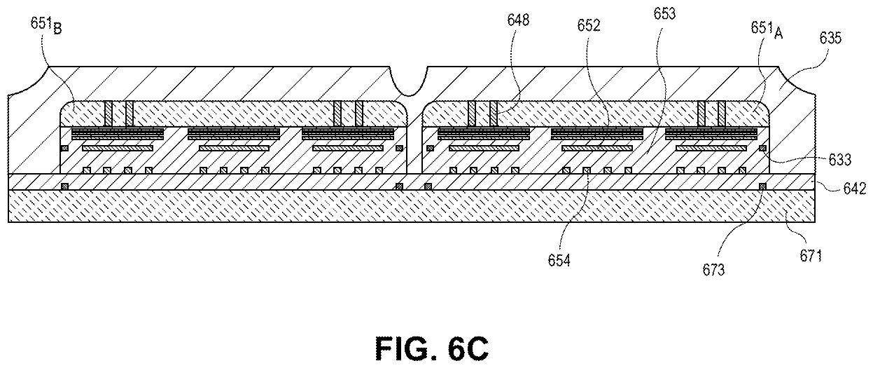

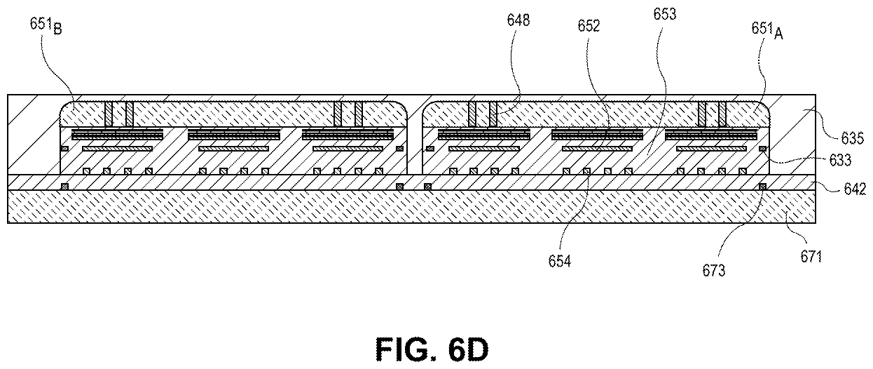

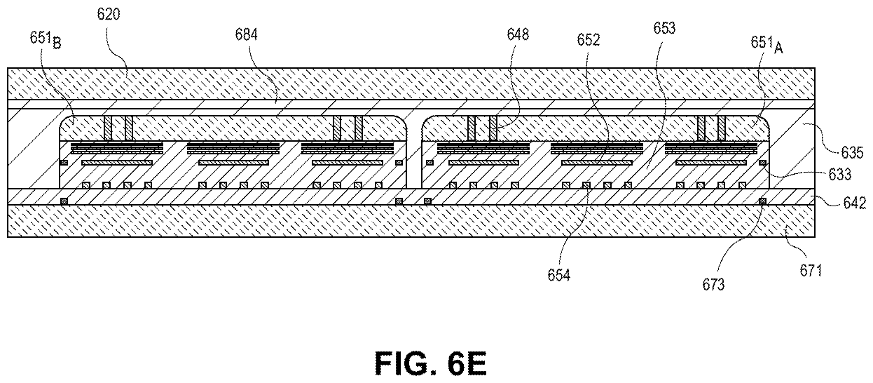

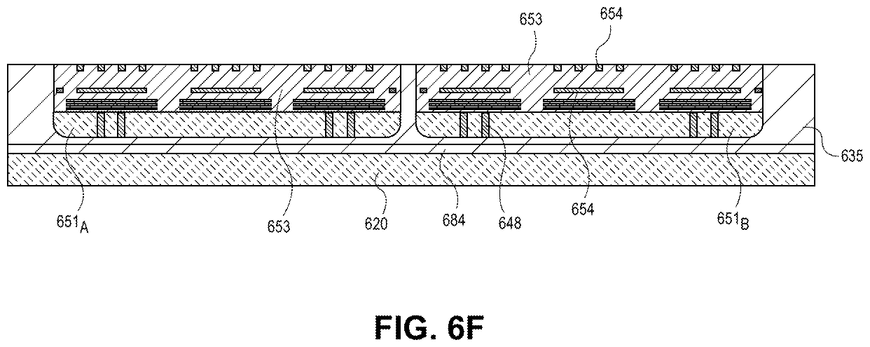

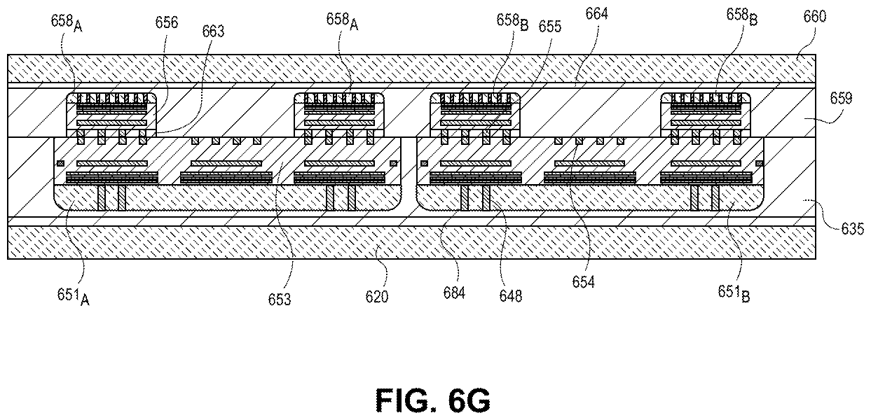

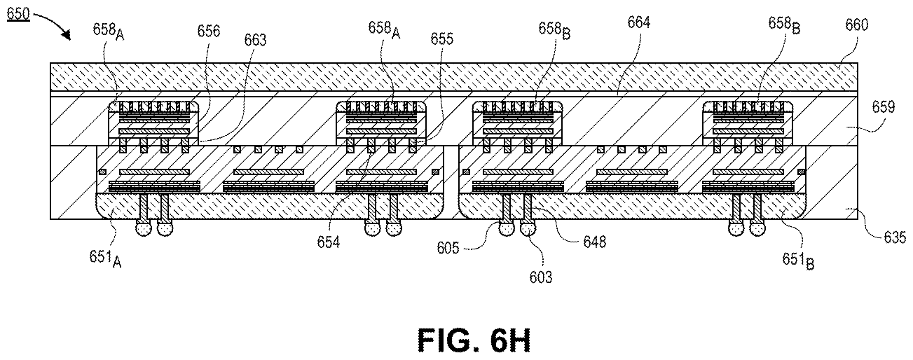

Referring now to FIGS. 6A-6H, a series of cross-sectional illustrations depicting a process for assembling a die module, such as the die module 550 shown in FIG. 5 is shown, in accordance with an embodiment.

Referring now to FIG. 6A. a cross-sectional illustration of a pair of base dies 651_{A} and 651_{B} that are coupled to a carrier 671 is shown, in accordance with an embodiment. In an embodiment, the base dies 651_{A}, and 651_{B} may be passive or active dies, as described above. In an embodiment, the base dies 651_{A}, and 651_{B} may comprise a silicon die or any other suitable semiconductor material. A plurality of routing layers 652 may be provided over the semiconductor material of the dies 651_{A}, and 651_{B}. For example, the routing layers 652 may include traces, vias, pads, and the like in order to electrically couple transistors and other structures on the die 651_{A}, and 651_{B} with pads 654. In an embodiment, the routing layers 652 may be formed in dielectric backend layers 653. For example, the backend layers 653 may comprise an oxide, such as an oxide of silicon (e.g., SiO₂).

In an embodiment, one or more fiducial marks 633 may be provided in the backend layers 653. The fiducial marks 633 may be marks used to improve alignment between the dies 651_{A}, and 651_{B} and the carrier 671. In an embodiment, any fiducial mark architecture may be used. For example, the fiducial marks may be a box, a cross, or the like. In the illustrated embodiment, a pair of fiducial marks 633 are shown on each die 651_{A}, and 651_{B}. However, it is to be appreciated that any number of fiducial marks may be used, in accordance with an embodiment. For example, fiducial marks 633 may be provided at each corner of the dies 651_{A}, and 651_{B}. In an embodiment, fiducial marks 673 may be provided on the first carrier 671 within a dielectric layer 642. The fiducial marks 673 can be aligned with the fiducial marks 633 on the dies 651_{A}, and 651_{B} in order to provide the proper orientation and positioning of the dies 651_{A}, and 651_{B} on the first carrier 671. In an embodiment, the fiducial marks 673 may be provided on a top surface of the first carrier 671, and a dielectric layer 672 surrounds the fiducial marks 673.

In an embodiment, the dies 651_{A}, and 651_{B} may comprise vias 648. The vias 648 may extend partially through a thickness of the dies 651. For example, in a subsequent processing operation, the dies 651_{A}, and 651_{B} may be recessed to expose the vias 648 in order to form a TSV architecture.

In an embodiment, the dielectric backend layers 653 may be set down onto the dielectric layer 672 over the first carrier 671. In an embodiment, the dielectric layer 653 and the dielectric layer 672 bond with a dielectric-to-dielectric bonding process. In some embodiments, van-der walls forces are sufficient to attach the two layers 653 and 672. In other embodiments, a low temperature annealing process (e.g., 160° C. to 180° C.) is used to fuse the dielectric layers 263 and 272 to make a permanent bond. In an embodiment, the first carrier 671 may be any suitable ridged material. For example, the first carrier 671 may be a silicon substrate or the like. In other embodiments the first carrier 671 may be a glass substrate.

It is to be appreciated that the dies 651_{A}, and 651_{B} may be KGDs. That is, the dies 651_{A}, and 651_{B} may be tested prior to being attached to the first carrier 671. In some embodiments, the dies 651_{A}, and 651_{B} are tested before being singulated, or the dies 651_{A}, and 651_{B} are tested after being singulated but before the attachment to the first carrier 671. Additionally, it is to be appreciated that foreign material may be provided between the dies 651_{A}, and 651_{B} and the first carrier 671. That is, the surfaces of the dies 651_{A}, and 651_{B} and the carrier 671 do not need to be pristine at this point in the assembly. This is because the interface between the dielectric layer 653 and the dielectric layer 672 will be polished away in a subsequent polishing operation.

Referring now to FIG. 2B, a cross-sectional illustration of the structure after a substrate thinning process is shown, in accordance with an embodiment. In an embodiment, a grinding process may be implemented in order to reduce a thickness of the dies 651_{A}, and 651_{B}. For example, the thickness of the dies 651_{A}, and 651_{B} may be reduced to approximately 20 μm or less, or approximately 10 μm or less. The grinding process may also result in the corners 632 of the dies 651_{A}, and 651_{B} being rounded. The rounded corners 632 are on the surface of the dies 651_{A}, and 651_{B} opposite from the pads 654. The thinning process may also result in the exposure of the backside of the vias 648.

Referring now to FIG. 6C, a cross-sectional illustration of the structure after a fill layer 635 is disposed around the dies 651_{A}, and 651_{B} is shown, in accordance with an embodiment. In an embodiment, the fill layer 635 may be an oxide or other filler material. In general, filler material is high temperature process compatible, has a low deposition temperature, and a low CTE. The fill layer 635 may fill the gaps between the dies 651_{A}, and 651_{B}. Portions of the fill layer 635 may be in direct contact with the dielectric layer 672. Additionally, while shown as a single fill layer 635, it is to be appreciated that multiple different fill layers may be used. For example, the fill layer 635 may comprise a first layer with improved mechanical properties, and a second layer over the first layer that has a faster deposition process.

Referring now to FIG. 6D, a cross-sectional illustration of the structure after the fill layer 635 is recessed is shown, in accordance with an embodiment. In an embodiment, the fill layer 635 may be recessed with a grinding or polishing process, such as a CMP process. In an embodiment, the fill layer 635 may be recessed so that a thin layer of the fill layer 635 remains over a back surface of the dies 651_{A}, and 651_{B}.

Referring now to FIG. 6E, a cross-sectional illustration of the structure after a second carrier 620 is attached to the first carrier 671 is shown, in accordance with an embodiment. In an embodiment, the second carrier 620 may be bonded to the fill layer 635 with a dielectric-to-dielectric bonding. For example, the second carrier 620 may include a dielectric layer 684, such as a silicon oxide (e.g., SiO₂) that is bonded to the fill layer 635. In an embodiment, the bonding strength is sufficient without an annealing process. In other embodiments, an annealing process is used to improve the bond. For example, an annealing process of between 160° C. and 180° C. may be used in some embodiments. Alternatively, an adhesive based bonding process between the second carrier 620 and the fill layer 635 may be used in some embodiments instead of dielectric-to-dielectric bond. In an embodiment, the second carrier 620 may be a semiconductor substrate, such as a silicon substrate. In other embodiments, the second carrier 620 may be another rigid material, such as glass or the like.

Referring now to FIG. 2F, a cross-sectional illustration of the structure after the first carrier 671 is removed is shown, in accordance with an embodiment. In an embodiment, the first carrier 671 and the dielectric layer 672 may be removed with a grinding or polishing process, such as a CMP process. The polishing process results in the exposure of pads 654 and the dielectric layer 653. At this point, the pads 654 are substantially clear of foreign material, and have a pristine surface.

Referring now to FIG. 6G, a cross-sectional illustration of the structure after the dies 658_{A}, and 658_{B} are bonded to base dies 651_{A}, and 651_{B} is shown, in accordance with an embodiment. In an embodiment, the bonding may be an HBI architecture. For example, the pads 655 of the dies 658_{A}, and 658_{B} may be provided over pads 654 on the base die 651_{A}, and 651_{B}. Additionally, the dielectric layer 663 of the dies 658_{A}, and 658_{B} may interface with the dielectric backend layer 653 of the base dies 651_{A}, and 651_{B}. In an embodiment, a low temperature process results in the dielectric layers 663 and the backend layers 653 bonding together. At a higher temperature anneal, the pads 655 may bond with the pads 654 with a solid state diffusion bonding process. In some embodiments, there may not be a discernable seam at the interface between the pads 654 and the pads 655.

In an embodiment, a pair of dies 658_{A}, and 658_{B} are bonded to each base die 651_{A}, and 651_{B}. For example, dies 658_{A} are bonded to base die 651_{A}, and dies 658_{B} are bonded to base die 651_{B}. While two dies 658_{A}, and 658_{B} are bonded to each base die 651_{A}, and 651_{B} in FIG. 6G, it is to be appreciated that any number of dies 658_{A}, and 658_{B} may be bonded to each base die 651_{A}, and 651_{B}. In an embodiment, the dies 658_{A}, and 658_{B} may include a processor, a graphics processor, a memory die, an SoC, or any other type of die 658_{A}, and 658_{B}. The dies 658_{A}, and 658_{B} may comprise backend layers 656 that include routing between the surface of the dies 658_{A}, and 658_{B} and the pads 655. In an embodiment, a carrier 660 may be bonded to the filler layer 659 by a dielectric layer 664 on the carrier 660.

Referring now to FIG. 6H, a cross-sectional illustration of the die module 650 after the TSVs 248 are revealed is shown, in accordance with an embodiment. In an embodiment, the TSVs 248 may be revealed by a removing the carrier 620 and polishing back a portion of the fill layer 635. After the TSVs 648 are exposed pads 605 may be formed over a backside of the base dies 651_{A}, and 651_{B}. In the illustrated embodiment, the pads 605 are shown as being directly on the base die 651_{A}, and 651_{B}. However, in some embodiments, one or more redistribution layers may be provided between the TSVs 648 and the pads 605. In an embodiment, bumps 603, such as solder bumps, may be plated on the pads 605 in order to prepare for attachment to a package substrate (not shown).

It is to be appreciated that only a single instance of the die module 650 is shown in the FIGS. 6A-6H. However, it is to be appreciated that a plurality of die modules 650 may be fabricated substantially in parallel using wafer level processes or other larger form factors. In such embodiments, the individual die modules 650 may be singulated after the operations shown in FIG. 6H in order to provide individual die modules 650.

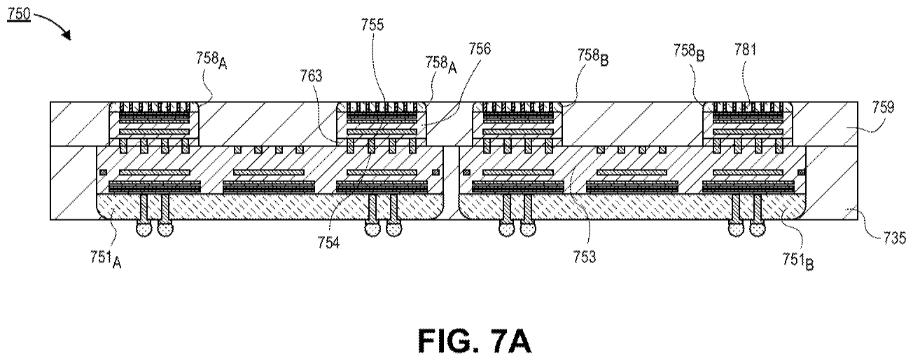

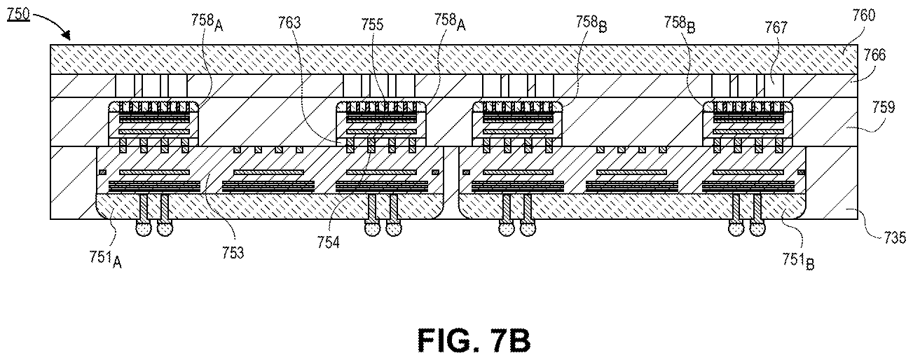

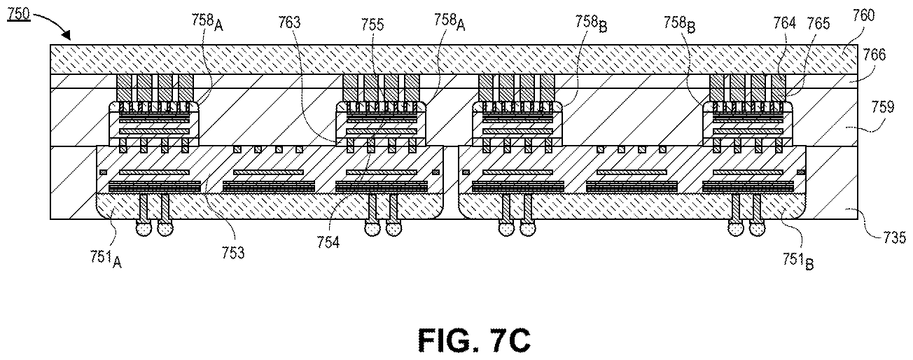

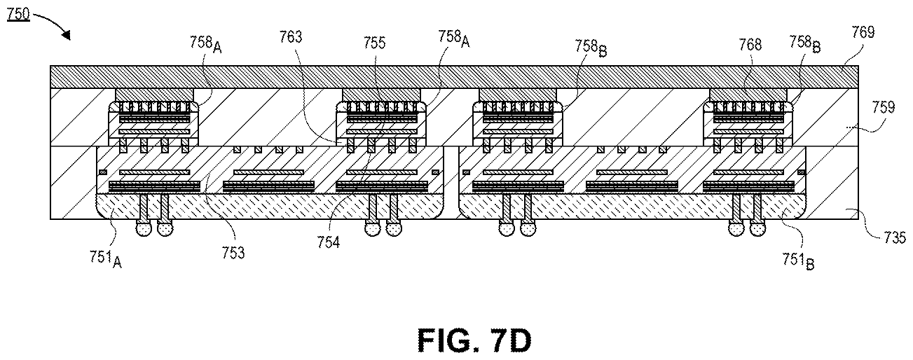

Referring now to FIGS. 7A-7D, a series of cross-sectional illustrations depicting a plurality of different die modules 750 is shown, in accordance with an embodiment. The illustrated embodiments may include improved thermal performance compared to the embodiment shown in FIG. 6H.

Referring now to FIG. 7A, a cross-sectional illustration of a die module 750 is shown, in accordance with an embodiment. In an embodiment, the die module 750 includes a pair of base dies 751_{A} and 751_{B}. The base dies 751_{A} and 751_{B} may have a backend dielectric layer 753. Pads 754 may be provided at a top surface of the backend dielectric layer 753. A plurality of second dies 758_{A} and 758_{B} may be coupled to the base dies 751_{A} and 751_{B}. For example, pads 755 may be provided in a dielectric layer 763 of the second dies 758_{A} and 758_{B}. In an embodiment, the pads 755 and the dielectric layer 763 may be bonded to the pads 754 and the backend dielectric layer 753 with an HBI architecture. That is, the pads 755 and 754 may undergo solid state diffusion in an annealing process in some embodiments. The base dies 751_{A} and 751_{B} may be in a fill layer 735.

In an embodiment, the second dies 758_{A} and 758_{B} may be surrounded by a filler layer 759. The filler layer 759 may be an oxide or the like. In some embodiments, the filler layer 759 may comprise two or more layers, as described in greater detail above. The second dies 758_{A} and 758_{B} may also comprise a backend dielectric layer 756 that couples the pads 755 to a die surface.

In the particular embodiment shown in FIG. 7A, the carrier substrate over a backside surface of the second dies 758_{A} and 758_{B} is omitted. Instead of the carrier, the die module 750 is polished back to expose the backside surfaces of the second dies 758_{A} and 758_{B}. Additionally, TSVs 781 may be formed through the second dies 758_{A} and 758_{B}. The TSVs 781 may be used for thermal regulation. That is, in some embodiments, the TSVs 781 are not electrically coupled to active circuitry of the second dies 758_{A} and 758_{B}.

Referring now to FIG. 7B, a cross-sectional illustration of a die module 750 is shown, in accordance with an additional embodiment. In an embodiment, the die module 750 includes a pair of base dies 751_{A} and 751_{B}. The base dies 751_{A} and 751_{B} may have a backend dielectric layer 753. Pads 754 may be provided at a top surface of the backend dielectric layer 753. A plurality of second dies 758_{A} and 758_{B} may be coupled to the base dies 751_{A} and 751_{B}. For example, pads 755 may be provided in a dielectric layer 763 of the second dies 758_{A} and 758_{B}. In an embodiment, the pads 755 and the dielectric layer 763 may be bonded to the pads 754 and the backend dielectric layer 753 with an HBI architecture. That is, the pads 755 and 754 may undergo solid state diffusion in an annealing process in some embodiments.

In contrast to the embodiment shown in FIG. 7A, the carrier 760 remains in the structure. However, the dielectric layer 766 between the carrier 760 and the fill layer 759 is increased in thickness, compared to the embodiment shown in FIG. 6H above. However, thermal control is still improved because fluidic channels 767 are provided through the dielectric layer 766. In an embodiment, a liquid cooling solution or a gas may be flown through the fluidic channels 767 in order to remove thermal energy from the backside of the second dies 758_{A} and 758_{B}. While shown as being only over the dies 758_{A} and 758_{B}, it is to be appreciated that the fluidic channels 767 may also be between the dies 758_{A} and 758_{B}. Similarly, the other thermal solutions described in FIGS. 7A-7D may also include thermal solutions between the dies 758. The second dies 758_{A} and 758_{B} may further comprise thermal TSVs 781 that pass thermal energy through the second dies 758_{A} and 758_{B}.

Referring now to FIG. 7C, a cross-sectional illustration of a die module 750 is shown, in accordance with another embodiment. In an embodiment, the die module 750 includes a pair of base dies 751_{A} and 751_{B}. The base dies 751_{A} and 751_{B} may have a backend dielectric layer 753. Pads 754 may be provided at a top surface of the backend dielectric layer 753. A plurality of second dies 758_{A} and 758_{B} may be coupled to the base dies 751_{A} and 751_{B}. For example, pads 755 may be provided in a dielectric layer 763 of the second dies 758_{A} and 758_{B}. In an embodiment, the pads 755 and the dielectric layer 763 may be bonded to the pads 754 and the backend dielectric layer 753 with an HBI architecture. That is, the pads 755 and 754 may undergo solid state diffusion in an annealing process in some embodiments.

As shown, pads 765 may be provided over a backside surface of the second dies 758_{A} and 758_{B}. Additionally, pads 764 may pass through the dielectric layer 766 on the carrier 760. The pads 765 and 764 may be bonded with an annealing process. The bonding may also result in the dielectric layer 766 bonding with the dielectric of the fill layer 759. In an embodiment, the pads 765 and 764 may be only for thermal control. That is, the pads 765 and 764 may not be electrically coupled to functional circuitry of the die module 750. The second dies 758_{A} and 758_{B} may further comprise thermal TSVs 781 that pass thermal energy through the second dies 758_{A} and 758_{B}.

Referring now to FIG. 7D, a cross-sectional illustration of a die module 750 is shown, in accordance with an additional embodiment. In an embodiment, the die module 750 includes a pair of base dies 751_{A} and 751_{B}. The base dies 751_{A} and 751_{B} may have a backend dielectric layer 753. Pads 754 may be provided at a top surface of the backend dielectric layer 753. A plurality of second dies 758_{A} and 758_{B} may be coupled to the base dies 751_{A} and 751_{B}. For example, pads 755 may be provided in a dielectric layer 763 of the second dies 758_{A} and 758_{B}. In an embodiment, the pads 755 and the dielectric layer 763 may be bonded to the pads 754 and the backend dielectric layer 753 with an HBI architecture. That is, the pads 755 and 754 may undergo solid state diffusion in an annealing process in some embodiments.

In an embodiment, the backside of the second dies 758_{A} and 758_{B} may be thermally coupled to the carrier 769 through metal slugs 768. In an embodiment, the carrier 769 may comprise a high thermal conductivity material. For example, the carrier 769 may comprise copper or the like. As such, a high amount of thermal energy may be pulled from the backside of the second dies 758_{A} and 758_{B}. The second dies 758_{A} and 758_{B} may further comprise thermal TSVs 781 that pass thermal energy through the second dies 758_{A} and 758_{B}.

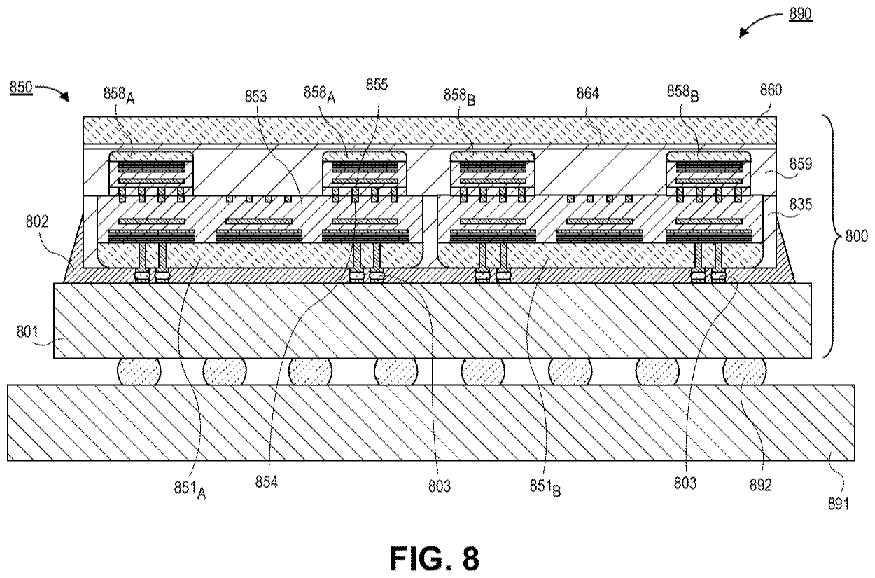

Referring now to FIG. 8, a cross-sectional illustration of an electronic system 890 is shown, in accordance with an embodiment. In an embodiment, the electronic system 890 may comprise a board 891, such as a PCB. In an embodiment, the board 891 is coupled to an electronic package 800 by interconnects 892. The interconnects 892 are shown as solder balls, but it is to be appreciated that sockets or the like may also couple the package substrate 801 to the board 891. In an embodiment, the electronic package 800 may comprise a package substrate 801 and a die module 850. The die module 850 may be coupled to the package substrate by interconnects 803. The interconnects 803 may be surrounded by an underfill 802.

In an embodiment, the die module 850 may be substantially similar to any of the die modules described in greater detail above. For example, the die module 850 may comprise a pair of base die 851_{A} and 851_{B}. A backend dielectric layer 853 may comprise pads 854 that are bonded to pads 855 of second dies 858_{A} and 858_{B}. The bonding interface between the second dies 858_{A} and 858_{B} and the base dies 851_{A} and 851_{B} may be an HBI architecture. In an embodiment, the second dies 858_{A} and 858_{B}may be surrounded by a fill layer 859, and the base dies 851_{A} and 851_{B} may be surrounded by a fill layer 835. The fill layer 859 may be bonded to a dielectric layer 864 that is attached to a carrier 860.

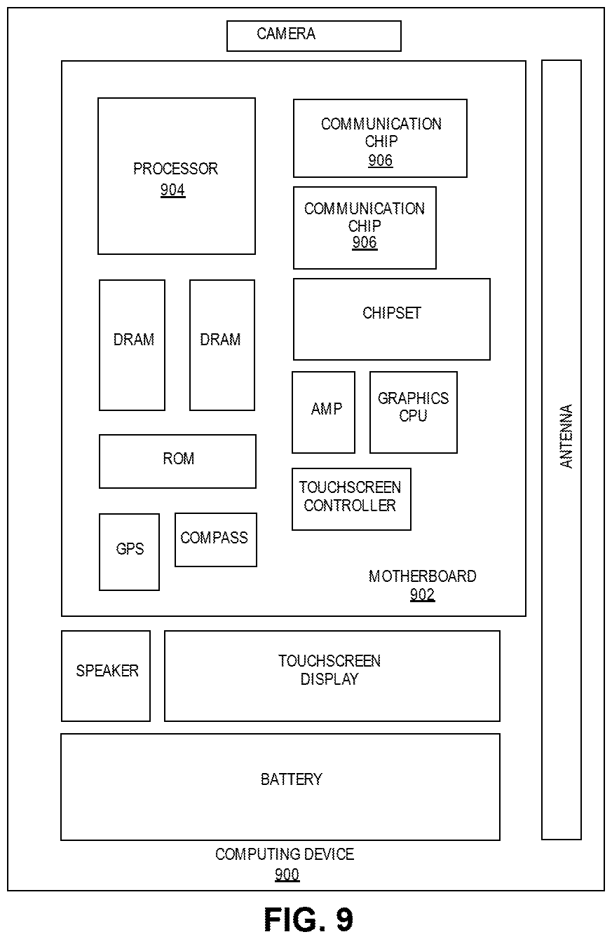

FIG. 9 illustrates a computing device 900 in accordance with one implementation of the invention. The computing device 900 houses a board 902. The board 902 may include a number of components, including but not limited to a processor 904 and at least one communication chip 906. The processor 904 is physically and electrically coupled to the board 902. In some implementations the at least one communication chip 906 is also physically and electrically coupled to the board 902. In further implementations, the communication chip 906 is part of the processor 904.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 906 enables wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 906 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 900 may include a plurality of communication chips 906. For instance, a first communication chip 906 may be dedicated to shorter range wireless communications such as Wi-Fi and Bluetooth and a second communication chip 906 may be dedicated to longer range wireless communications such as GPS, EDGE, GPRS, CDMA, WiMAX, LTE, Ev-DO, and others.

The processor 904 of the computing device 900 includes an integrated circuit die packaged within the processor 904. In some implementations of the invention, the integrated circuit die of the processor may be part of an electronic package that comprises a die module with a base die that is electrically coupled to one or more top dies by an HBI architecture, in accordance with embodiments described herein. The term “processor” may refer to any device or portion of a device that processes electronic data from registers and/or memory to transform that electronic data into other electronic data that may be stored in registers and/or memory.

The communication chip 906 also includes an integrated circuit die packaged within the communication chip 906. In accordance with another implementation of the invention, the integrated circuit die of the communication chip may be part of an electronic package that comprises a die module with a base die that is electrically coupled to one or more top dies by an HBI architecture, bottom-up via structures, and/or mm-wave launchers, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: a die module, comprising: a first die with a set of first pads with surfaces that are substantially coplanar with a surface of a first dielectric layer; and a second die with a set of second pads with surfaces that are substantially coplanar with a surface of a second dielectric layer, and wherein the first pads are bonded to the second pads and the first dielectric layer is bonded to the second dielectric layer.

Example 2: the die module of Example 1, wherein a width of the first die is greater than a width of the second die.

Example 3: the die module of Example 2, wherein the first die further comprises a third set of metal interconnects with surfaces that are substantially coplanar with the surface of the first dielectric layer, and wherein the die module further comprises: a third die with a set of fourth pads that are substantially coplanar with a surface of a third dielectric layer, and wherein the third pads are bonded to the fourth pads and the first dielectric layer is bonded to the third dielectric layer.

Example 4: the die module of Examples 1-3, wherein corners of the second die are rounded.

Example 5: the die module of Examples 1-4, further comprising: a carrier over the second die.

Example 6: the die module of Example 5, wherein the second die is embedded in a dielectric, and wherein the carrier is attached to the second die by a dielectric-to-dielectric bond.

Example 7: the die module of Example 5, wherein the carrier is a silicon substrate.

Example 8: the die module of Examples 1-7, further comprising: through die via through a thickness of the second die.

Example 9: the die module of Examples 1-8, further comprising: channels over the second die.

Example 10: the die module of Examples 1-9, further comprising: a carrier over the second die, wherein the carrier is coupled to the second die by a hybrid bonding interface.

Example 11: the die module of Examples 1-10, wherein a backside of the second die is coupled to a metal substrate.

Example 12: the die module of Examples 1-11, wherein the first die comprises first fiducial marks, and wherein the second die comprises second fiducial marks that are aligned with the first fiducial marks.

Example 13: the die module of Examples 1-14, wherein the first die comprises through die vias.

Example 14: the die module of Example 13, wherein pads are coupled to the through die vias.

Example 15: a method of assembling a die module, comprising: attaching a plurality of dies to a first carrier, wherein each die comprises metal contacts that are embedded in a dielectric layer; reducing a thickness of the plurality of dies; disposing a filler around the plurality of dies; attaching a second carrier to the filler; removing the first carrier; recessing the dielectric layer to expose the metal contacts; and attaching the plurality of dies to a base die with a hybrid bonding interconnect using the metal contacts.

Example 16: the method of Example 15, wherein the base die comprises embedded vias.

Example 17: the method of Example 16, further comprising: recessing the base die to expose the embedded vias.

Example 18: the method of Examples 15-17, wherein the filler comprises two or more material layers.

Example 19: the method of Examples 15-18, wherein the second carrier is attached to the filler with an oxide-to-oxide bond.

Example 20: the method of Examples 15-19, wherein recessing the dielectric layer to expose the metal contacts is done with a chemical mechanical polishing (CMP) process.

Example 21: the method of Example 20, wherein attaching the plurality of dies to a base die with a hybrid bonding interconnect is done immediately after the CMP process.

Example 22: the method of Examples 15-21, further comprising: removing the second carrier after the hybrid bonding.

Example 23: the method of Examples 15-22, wherein corners of the plurality of dies are rounded.

Example 24: an electronic system, comprising: a board; a package substrate coupled to the board; and a die module coupled to the package substrate, wherein the die module comprises: a first die with a set of first pads with surfaces that are substantially coplanar with a surface of a first dielectric layer; and a second die with a set of second pads with surfaces that are substantially coplanar with a surface of a second dielectric layer, and wherein the first pads are bonded to the second pads and the first dielectric layer is bonded to the second dielectric layer.

Example 25: the electronic system of Example 24, wherein corners of the second die are rounded.

Example 26: a die module, comprising: a first die; a second die adjacent to the first die; a plurality of third dies coupled to the first die with hybrid bonding interconnects; and a plurality of fourth dies coupled to the second die with hybrid bonding interconnects.

Example 27: the die module of Example 26, further comprising: a carrier over the plurality of third dies and the plurality of fourth dies.

Example 28: the die module of Example 26 or Example 27, wherein the first dies are surrounded by a fill layer.

Example 29: the die module of Example 28, wherein the fill layer comprises two or more material layers.

Example 30: the die module of Example 28, wherein the plurality of third dies and the plurality of fourth dies are surrounded by a second fill layer.

Example 31: the die module of Examples 26-30, wherein corners of the first die and corners of the second die are rounded.

Example 32: the die module of Example 31, wherein the corners facing away from the plurality of third dies and the plurality of fourth dies are rounded.

Example 33: the die module of Example 31, wherein corners of the plurality of third dies and corners of the plurality of fourth dies are rounded.

Example 34: the die module of Example 33, wherein the rounded corners of the plurality of third dies and the rounded corners of the plurality of fourth dies are facing away from the first die and the second die.

Example 35: the die module of Examples 26-34, wherein the first die and the second die comprise through die vias.

Example 36: the die module of Examples 26-35, wherein the plurality of third dies and the plurality of fourth dies comprise through die vias.

Example 37: the die module of Examples 26-35, further comprising: channels above the plurality of third dies and the plurality of fourth dies.

Example 38: the die module of Examples 26-36, wherein the plurality of third dies and the plurality of fourth dies are bonded to a carrier with a hybrid bonding interconnect architecture.

Example 39: the die module of Examples 26-38, wherein the plurality of third dies and the plurality of fourth dies are thermally coupled to a metal substrate.

Example 40: the die module of Examples 26-39, wherein the plurality of third dies and the plurality of fourth dies have a thickness of approximately 10 μm or less.

Example 41: a method of forming a die module, comprising: attaching a first die and a second die to a first carrier; disposing a fill layer around the first die and the second die; attaching a second carrier to the fill layer; removing the first carrier; attaching a plurality of third dies to the first die with a hybrid bonding architecture; attaching a plurality of fourth dies to the second die with a hybrid bonding architecture; and removing the second carrier.

Example 42: the method of Example 41, wherein the plurality of third dies and the plurality of fourth dies are coupled to a third carrier.

Example 43: the method of Example 42, wherein the third carrier is bonded to the plurality of third dies and the plurality of fourth dies by an oxide-to-oxide bond.

Example 44: the method of Example 43, wherein the oxide-to-oxide bond has a thickness less than 1 μm.

Example 45: the method of Examples 41-44, wherein the first die and the second die have rounded corners.

Example 46: the method of Examples 41-45, wherein the plurality of third dies and the plurality of fourth dies have rounded corners.

Example 47: the method of Examples 41-46, further comprising: recessing the first die and the second die to expose through die vias.

Example 48: an electronic system, comprising: a board; a package substrate coupled to the board; and a die module coupled to the package substrate, wherein the die module comprises: a first die; a second die adjacent to the first die; a plurality of third dies coupled to the first die with hybrid bonding interconnects; and a plurality of fourth dies coupled to the second die with hybrid bonding interconnects.

Example 49: an electronic system of Example 48, further comprising: a carrier over the plurality of third dies and the plurality of fourth dies.

Example 50: the electronic system of Examples 48 or Example 49, wherein the first dies are surrounded by a fill layer.

What is claimed is:

1. An electronic system, comprising:
a substrate having a top side above a bottom side;
solder balls beneath the bottom side of the substrate;
a first base die coupled to the top side of the substrate by first interconnects, the first base die having through silicon vias (TSVs) therein;
a second base die coupled to the top side of the substrate by second interconnects, the second base die having TSVs therein, and the second base die laterally spaced apart from the first base die;
an underfill surrounding the first interconnects and the second interconnects;
a first processor die over and coupled to the first base die;
a second processor die over and coupled to the first base die, the second processor die laterally spaced apart from the first processor die;
a third processor die over and coupled to the second base die;
a fourth processor die over and coupled to the second base die, the fourth processor die laterally spaced apart from the third processor die; and
a silicon carrier over the first processor die and the second processor die.

2. The electronic system of claim 1, wherein the silicon carrier is over the third processor die and the fourth processor die.

3. The electronic system of claim 1, wherein the first processor die and the second processor die are hybrid bonded to the first base die.

4. The electronic system of claim 3, wherein the third processor die and the fourth processor die are hybrid bonded to the second base die.

5. The electronic system of claim 1, wherein the silicon carrier is coupled to the first processor die and the second processor die by a dielectric layer.

6. The electronic system of claim 1, wherein the top surface of the first base die has a bonding region with no processor die thereon, and the top surface of the second base die has a bonding region with no processor die thereon.

7. The electronic system of claim 6, wherein the bonding region of the first base die is between the first processor die and the second processor die, and wherein the bonding region of the second base die is between the third processor die and the fourth processor die.

8. The electronic system of claim 6, wherein a first portion of the TSVs of the first base die are beneath the first processor die, and a second portion of the TSVs of the first base die are beneath the second processor die, and wherein there are no TSVs beneath the bonding region of the first base die.

9. The electronic system of claim 1, wherein the substrate is a package substrate.

10. An electronic system, comprising:
a substrate having a top side above a bottom side;
solder balls beneath the bottom side of the substrate;
a first die coupled to the top side of the substrate by first interconnects, the first die having through silicon vias (TSVs) therein;
a second die coupled to the top side of the substrate by second interconnects, the second die having TSVs therein, and the second die laterally spaced apart from the first die;
an underfill surrounding the first interconnects and the second interconnects;
a third die over and coupled to the first die;
a fourth die over and coupled to the first die, the fourth die laterally spaced apart from the third die;
a fifth die over and coupled to the second die;
a sixth die over and coupled to the second die, the sixth processor die laterally spaced apart from the fifth die; and
a silicon carrier over the third die and the fourth die.

11. The electronic system of claim 10, wherein the silicon carrier is over the fifth die and the sixth die.

12. The electronic system of claim 10, wherein the third die and the fourth die are hybrid bonded to the first die, and wherein the fifth die and the sixth die are hybrid bonded to the second die.

13. The electronic system of claim 10, wherein the silicon carrier is coupled to the third die and the fourth die by a dielectric layer.

14. A method of fabricating an electronic system, the method comprising:
providing a substrate having a top side above a bottom side;
forming solder balls beneath the bottom side of the substrate;
coupling a first base die to the top side of the substrate by first interconnects, the first base die having through silicon vias (TSVs) therein;
coupling a second base die to the top side of the substrate by second interconnects, the second base die having TSVs therein, and the second base die laterally spaced apart from the first base die;
forming an underfill surrounding the first interconnects and the second interconnects;
coupling a first processor die to the first base die;
coupling a second processor die to the first base die, the second processor die laterally spaced apart from the first processor die;
coupling a third processor die to the second base die;
coupling a fourth processor die over to the second base die, the fourth processor die laterally spaced apart from the third processor die; and
providing a silicon carrier over the first processor die and the second processor die.

15. The method of claim 14, wherein the silicon carrier is over the third processor die and the fourth processor die.

16. The method of claim 14, wherein the first processor die and the second processor die are hybrid bonded to the first base die.

17. The method of claim 16, wherein the third processor die and the fourth processor die are hybrid bonded to the second base die.

18. The method of claim 14, wherein the silicon carrier is coupled to the first processor die and the second processor die by a dielectric layer.

19. The method of claim 14, wherein the top surface of the first base die has a bonding region with no processor die thereon, and the top surface of the second base die has a bonding region with no processor die thereon.

20. The method of claim 19, wherein the bonding region of the first base die is between the first processor die and the second processor die, and wherein the bonding region of the second base die is between the third processor die and the fourth processor die.

21. The method of claim 19, wherein a first portion of the TSVs of the first base die are beneath the first processor die, and a second portion of the TSVs of the first base die are beneath the second processor die, and wherein there are no TSVs beneath the bonding region of the first base die.
